(19) United States
(12) Patent Application Publication
(10) Pub. No.: US 2006/0289934 A1
(43) Pub. Date: Dec. 28, 2006

(54) Semiconductor device, liquid crystal display panel, electronic device, and method of manufacturing semiconductor device

(75) Inventors: Hiroshi Tanabe, Tokyo (JP); Shunji Tsuida, Tokyo (JP)

Correspondence Address: Paul J. Esatto, Jr.;Scully, Scott, Murphy & Presser, 400 Garden City Plaza, Garden City, NY, 11530, US

(73) Assignee: NEC CORPORATION, TOKYO (JP)

(21) Appl. No.: 11/438,846

(22) Filed: May 23, 2006

(30) Foreign Application Priority Data
May 23, 2005 (JP) 2005-149582

(51) Int. Cl. H01L 27/12

(52) U.S. Cl. 257/347

(57) ABSTRACT

In a plurality of transistors in which the thresholds that are required in the circuit design are equal, a transistor having an initial threshold at a lower limit within an acceptable range of the required threshold is arranged at a circuit position where an absolute value of a threshold voltage increases by operating, and a transistor having an initial threshold at an upper limit within an acceptable range of the required threshold is arranged at a circuit position where an absolute value of a threshold voltage decreases by operating.

### BACKGROUND OF THE INVENTION

1. Field of the Invention

The present invention relates to a semiconductor device provided with a plurality of transistors, a liquid crystal display panel and an electronic device provided with the semiconductor device, and a method of manufacturing a semiconductor device.

2. Description of the Related Art

Conventionally, an LSI (Large Scale Integrated circuit) including a memory, a CPU (Central Processing Unit), and the like is manufactured by a known process (hereinafter, called an LSI process) for forming a fine transistor on a surface of a silicon wafer.

In LSIs, in order to promote an increase in memory capacity, and an increase in speed and a reduction in power consumption of a CPU, transistors have been made smaller and the operating voltage have been reduced, as compared with the prior art.

On the other hand, recently, in order to provide a liquid crystal display panel with a larger-screen, higher-resolution, and lower-power consumption, thin film transistors have been actively developed. In the liquid crystal display panel, generally, a semiconductor layer is formed on an insulating substrate, which becomes a base, and the semiconductor layer is used as the active layer of the thin film transistor.

Thin film transistors using amorphous silicon hydride as an active layer or polycrystalline silicon (polysilicon) as an active layer are in practical use.

Thin film transistors that use polycrystalline silicon as active layers, include a high-temperature polysilicon thin film transistor and a low-temperature polysilicon thin film transistor. The high-temperature polysilicon thin film transistor uses quartz as a base and is manufactured by the heat treatment process at about 1000° C., which is similar to the above LSI process. Additionally, as a high-temperature polysilicon thin film transistor, there is also a polysilicon thin film transistor that is laminated on a silicon wafer, like a TFT (Thin Film Transistor) loaded type SRAM (Static Random Access Memory).

On the other hand, a low-temperature polysilicon thin film transistor uses glass having a low melting point and without alkaline metal as a base and is manufactured by the heat treatment at about 500° C. For example, as disclosed in Japanese Patent Laid-Open No. 9-116159 and 10-242471, a low-temperature temperature polysilicon thin film transistor is provided with a source/drain electrode that is formed on an insulating substrate, a polysilicon layer, which is a channel, a gate insulating film, and a gate electrode.

When the low-temperature polysilicon thin film transistor is manufactured, the activation process at about 500° C. for the purpose of activating impurities in a source/drain region, the hydrogen plasma process at about 300° C. for the purpose of hydrogen passivation, and the heat treatment from 200° C. to 300° C. for repairing plasma damages that are introduced in the dry-etching process or the like are performed. Such a low-temperature polysilicon thin film transistor is also in practical use as a driving device for the liquid crystal display panel.

However, there are following problems in the above-mentioned prior art. In the low-temperature polysilicon thin film transistor, it is known that a phenomenon that has not been understood tends to occur, for example, it is known that characteristics are degraded when a low-temperature polysilicon thin film transistor is operated for a long period, as compared with transistors that are manufactured by the conventional LSI process.

As the reason, it can be considered that a low-temperature polysilicon thin film transistor is different from transistors manufactured by the LSI process in MOS (Metal Oxide Semiconductor) interfaces that determine an element characteristic, especially, an OS (Oxide-Semiconductor) interface.

The transistor manufactured by the LSI process is provided with monocrystalline silicon and a good-quality thermal oxide film in the OS interface. On the other hand, the low-temperature polysilicon thin film transistor is provided with polycrystalline silicon whose the orientation is random and a silicon dioxide film including much water (specifically, OH base) in the OS interface.

Polycrystalline silicon includes more non-bonds (dangling bonds) of Si atoms than the monocrystalline silicon, and the dangling bonds act as a trap for carriers.

In order to reduce such a trap for carriers, the plasma hydrogen process for terminating the dangling bonds with hydrogen is applied when the low-temperature polysilicon thin film transistor is manufactured. However, the hydrogen-silicon bonding formed by the plasma hydrogen process is not always stable, and dissociation or recombination sometimes occurs when an electric field is applied.

On the other hand, the silicon dioxide film causes an increase in the fixed charge density because OH bases exit. Also, dissociation or recombination of Si—OH combination sometimes occurs when an electric field is applied.

Therefore, a low-temperature polysilicon thin film transistor has a problem in that the OS interface thereof tends to be degraded when an electric field is applied. Accordingly, when a circuit including the low-temperature polysilicon thin film transistor is operated for a long period, there is a possibility that the characteristic of the low-temperature polysilicon thin film transistor changes from the initial characteristic and the circuit operation becomes unstable.

### SUMMARY OF THE INVENTION

Accordingly, it is an object of the present invention to provide a semiconductor device that operates stably even if being operated for a long period, a liquid crystal display panel and an electronic device that are provided with the semiconductor device, and a method of manufacturing a semiconductor device.

To attain the above-mentioned object, in a plurality of transistors in which the thresholds that are required in the circuit design are equal, a transistor having an initial threshold at a lower limit within an acceptable range of the required threshold is arranged at a circuit position where an absolute value of a threshold voltage increases by operating the transistor, and a transistor having an initial threshold at an upper limit within an acceptable range of the required threshold is arranged at a circuit position where an absolute value of a threshold voltage decreases by operating the transistor.

In the semiconductor device, as described above, since the threshold of each transistor varies in a direction to compensate for differences of the initial thresholds even if the semiconductor device is operated for a long period, there is no case in which the difference of thresholds of each transistor becomes large so as to exceed the warranty range of the circuit operation. Therefore, it is possible to obtain a semiconductor device that operates stably without malfunctions even if it is operated for a long period. Accordingly, a liquid crystal display panel and an electronic device having long operating life can be obtained when such a semiconductor device is used.

The above and other objects, features, and advantages of the present invention will become apparent from the following description with reference to the accompanying drawings which illustrate examples of the present invention.

### BRIEF DESCRIPTION OF THE DRAWINGS

FIG. 1 is a block diagram showing a configuration of a semiconductor device according to a first embodiment of the present invention;

FIG. 2 is a circuit diagram showing a configuration of a shift register shown in FIG. 1;

FIG. 3 is a side cross-sectional view showing the configuration of transistors shown in FIG. 2;

FIG. 4 is a timing chart showing an operation of shift register SR1 shown in FIG. 2;

FIG. 5A is a graph showing time-variation of a static characteristic of transistor T5 shown in FIG. 2;

FIG. 5B is a graph showing time-variation of a static characteristic of transistor T6 shown in FIG. 2;

FIG. 6A is a graph showing time-variation of a static characteristic of a case where the present invention is applied to transistors T5 and T6 shown in FIG. 2,

FIG. 6B is a graph showing time-variation of a static characteristic of a case where the present invention is not applied to transistors T5 and T6 shown in FIG. 2;

FIG. 7 is a side cross-sectional view showing the configuration of a semiconductor device according to a second embodiment of the present invention;

FIG. 8 is a side cross-sectional view showing the configuration of a semiconductor device according to a third embodiment of the present invention;

FIG. 9 is a side cross-sectional view showing the configuration of a semiconductor device according to a fourth embodiment of the present invention;

FIGS. 10A to 10H are side cross-sectional views showing the procedure of a method of manufacturing the semiconductor device according to the first embodiment;

FIG. 11 is a graph showing an example of static characteristics of the transistors manufactured by the manufacturing method shown in FIGS. 10A to 10H;

FIG. 12 is a graph showing an example of static characteristics of transistors manufactured according to a sixth embodiment;

FIG. 13 is a graph showing an example of static characteristics of transistors manufactured according to a seventh embodiment;

FIGS. 14A to 14F are side cross-sectional views showing the procedure of a method of manufacturing the semiconductor device according to the fourth embodiment;

FIG. 15 is a side cross-sectional view showing the procedure of a manufacturing method when transistors in a pixel circuit are formed;

FIG. 16 is a perspective exploded view showing an example of a structure of a liquid crystal display panel; and

FIG. 17 is a perspective exploded view showing an example of a structure of an electronic device according to the present invention.

### DESCRIPTION OF THE PREFERRED EMBODIMENTS

### First Embodiment

A semiconductor device according to the first embodiment is a driver circuit for driving a liquid crystal display panel, which includes P-channel transistors. Hereinafter, the driver circuit is called scanning circuit 1.

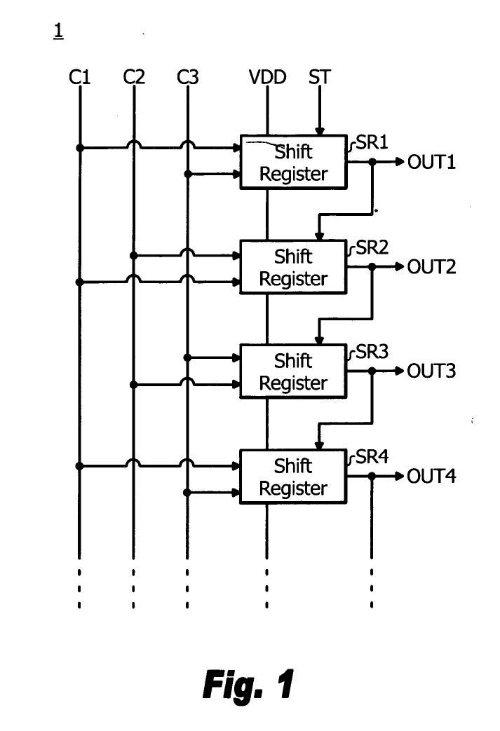

As shown in FIG. 1, scanning circuit 1 is formed on glass substrate 2 (see FIG. 3). Scanning circuit 1 is provided with a plurality of shift registers (SR1, SR2, SR3, SR4, . . . ) that are connected in series. Start pulse ST is input to shift register SR1 at the first stage, and output signals of previous shift registers are input to shift registers at the second and subsequent stages.

Two clock signals in three clock signals C1 to C3 are input to each shift register. In other words, when k is an integer of zero or more, clock signals C3 and C1 are input to the shift register at the (3k+1)-th stage, clock signals C1 and C2 are input to the shift register at the (3k+2)-th stage, and clock signals C2 and C3 are input to the shift register at the (3k+3)-th stage.

Further, power supply voltage VDD is supplied to each shift register.

Shift register SR1 outputs signal OUT1 so that the phase of start pulse ST is shifted by clock signal C1. Shift register SR2 outputs signal OUT2 so that the phase of signal OUT1 output from shift register SR1 is shifted by clock signal C2. Shift register SRn (n is an integer of 2 or more) outputs signal OUTn so that the phase of signal OUT(n−1) output from shift register SR(n−1) is shifted. In this way, the phase of start pulse ST is sequentially shifted in synchronization with the clock signals.

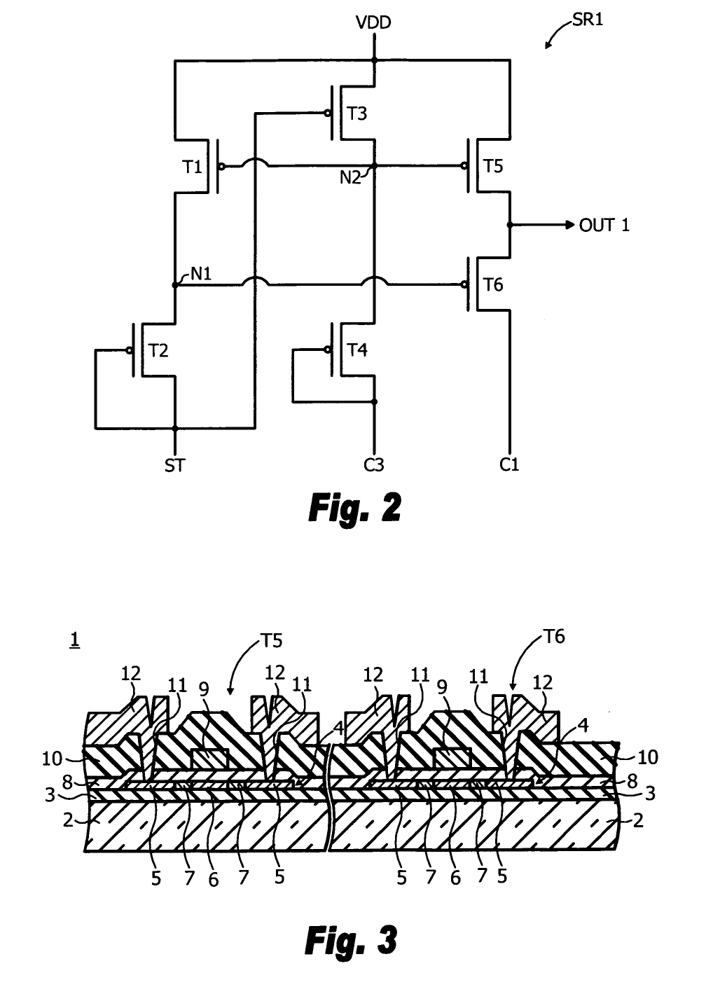

As shown in FIG. 2, shift register SR1 is provided with six transistors T1 to T6. Transistors T1 to T6 are thin film transistors formed on glass substrate 2 (see FIG. 3) and are P-channel transistors, each of which provides the same current drivability.

In transistor T1, power supply voltage VDD is applied to either the source or the drain, and the other is connected to the source or the drain of transistor T2. In transistor T3, power supply voltage VDD is applied to either the source or the drain, and the other is connected to the source or the drain of transistor T4. In transistor T5, power supply voltage VDD is applied to either the source or the drain, and the other is connected to the source or the drain of transistor T6.

Start pulse ST is input to the other of the source or the drain of transistor T2. Clock C3 is input to the other of the source or the drain of transistor T4. Clock C1 is input to the other of the source or the drain of transistor T6.

Further, start pulse ST is input to the gates of transistors T2 and T3. Clock C3 is input to the gate of transistor T4. The gate of transistor T6 is connected to node N1 for connecting transistor T1 and transistor T2. The gates of transistors T1 and T5 are connected to node N2 for connecting transistor T3 and transistor T4.

The potential at a node for connecting transistor T5 and transistor T6 is output as signal OUT1.

Next, the function of each transistor is explained.

Transistor T2 is in a conduction state when start pulse ST is at a Low level, and supplies a potential that is higher than the Low level of start pulse ST added to threshold (Vt), to node N1.

Transistor T4 is in a conduction state when clock signal C3 is at the Low level, and supplies a potential that is higher than the Low level of clock signal C3 added to threshold (Vt), to node N2.

Transistor T5 is in a conduction state when the potential of node N2 is (Low level+Vt), and outputs a High level as signal OUT1.

Transistor T6 is in a conduction state when node N1 is at a low potential (Low level+Vt or still lower than the Low level), and supplies the potential of clock signal C1 to output OUT1.

Transistor T3 is in a conduction state when start pulse ST is at the Low level, and supplies the High level to node N2.

Transistor T1 is in a conduction state when the potential of node N2 is (Low level+Vt), and supplies the High level to node N1.

Shift register SRn (n is an integer of 2 or more) of the second or subsequent stage is similar to shift register SR1. However, signals to be input are different. In other words, signal OUT(n−1) output from shift register SR(n−1) of the previous stage is input to shift register SRn.

Incidentally, when k is an integer of 0 or more, clock signals C3 and C1 are input to shift register SR(3k+1), clock signals C1 and C2 are input to shift register SR(3k+2), and clock signals C2 and C3 are input to shift register SR(3k+3).

FIG. 3 shows the structures of transistors T5 and T6 shown in FIG. 2.

As shown in FIG. 3, scanning circuit 1 is formed on glass substrate 2.

Silicon oxide film 3, which is a protection film for the substrate, is formed on glass substrate 2, and polycrystalline silicon film 4 in an island shape is arranged thereon. Polycrystalline silicon film 4 is an active layer of transistors.

Both end portions of polycrystalline silicon film 4 are source/drain regions 5 of transistors T5 and T6. Also, the central portions of polycrystalline silicon film 4 are channel regions 6 of transistors T5 and T6. Further, boundary portions between source/drain regions 5 and channel regions 6 are LDD (Lightly Doped Drain) regions 7.

For example, phosphorus having a 1×10¹² cm⁻² dose is implanted into channel region 6 of transistor T5, and phosphorus having a 3×10¹² cm⁻² dose is implanted into channel region 6 of transistor T6. Therefore, channel regions 6 of transistor T5 and transistor T6 are different in doping concentrations. With this arrangement, an absolute value of an initial threshold voltage of transistor T5 immediately after manufacture (initial threshold) is set smaller than the initial threshold of transistor T6. Also, the initial threshold of transistor T5 is set to a lower limit within an acceptable range that is necessary for a circuit, and the initial threshold of transistor T6 is set to an upper limit within an acceptable range that is necessary for the circuit.

Further, gate insulating film 8 made of, for example, silicon oxide, is formed on silicon oxide film 3 so as to cover polycrystalline silicon film 4, and gate electrode 9 made of, for example, polysilicon, is formed on a region directly above channel region 6 on gate insulating film 8.

Further, interlayer insulating film 10 made of, for example, silicon oxide, is formed on gate insulating film 8 so as to cover gate electrode 9. Contact hole 11 is formed in interlayer insulating film 10 on source/drain region 5, and wire 12 that is to be connected to source/drain region 5 is arranged in contact hole 11 and on interlayer insulating film 10.

Next, explanations are given of the operation of the semiconductor device according the first embodiment.

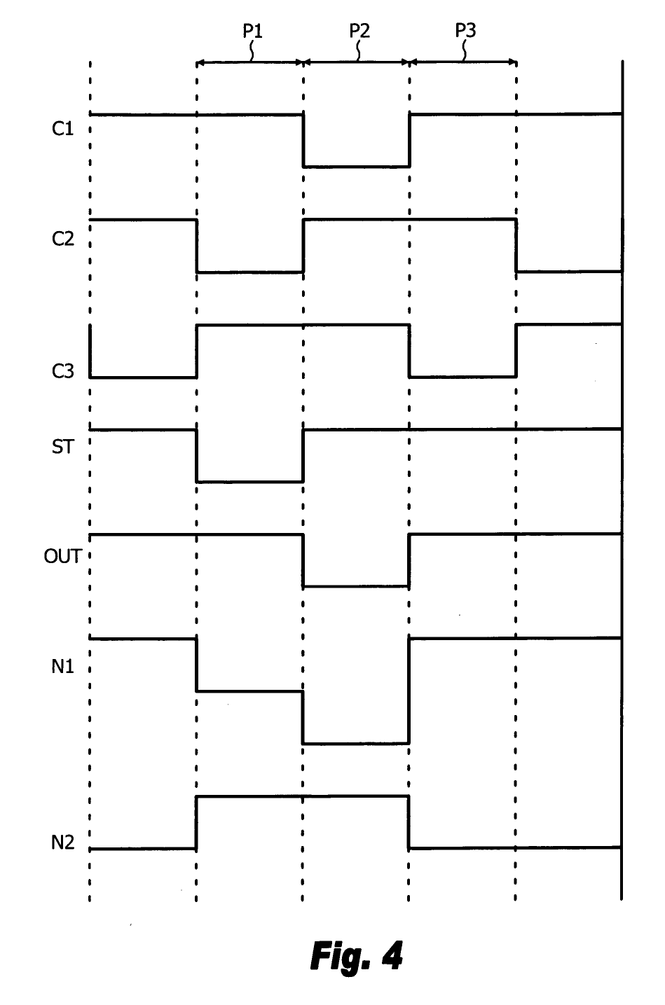

As shown in FIG. 4, assuming that clock signal C1 is at the High level, clock signal C2 is at the High level, clock signal C3 is at the Low level, and start pulse St is at the High level, in the initial state. Incidentally, assume that the potential at the High level of clock signals C1 to C3 and start pulse ST is power supply voltage VDD and the potential at the Low level is VSS.

At this time, since clock signal C3 is at the Low level, transistor T4 of shift register SR1 is in a conduction state, and since start pulse ST is at the High level, transistors T2 and T3 of shift register SR1 are in a non-conduction state. Therefore, node N2 is at potential (VSS+Vt) that is higher than the Low level by threshold voltage (Vt).

Accordingly, transistors T1 and T5 are in a conduction state, the potential at node N1 is at the High level (power supply voltage VDD), and transistor T6 is in a non-conduction state. As a result, since transistor T5 is a in conduction state and transistor T6 is in a non-conduction state, signal OUT1 is at the High level.

Then, during period P1 shown in FIG. 4, when start pulse ST is at the Low level and clock signal C3 is at the High level, transistors T2, T3 are in a conduction state.

At this time, the potential of node N1 varies to a potential (VSS+Vt) that is higher than the Low level of start pulse ST added to threshold voltage Vt. Also, since transistor T4 is in a non-conduction state, node N2 is at the High level and transistors T1 and T5 are in a non-conduction state.

Accordingly, transistor T6 is in a conduction state, however, signal OUT1 is maintained at the High level because clock signal C1 is at the High level.

Successively, during period P2, start pulse ST is at the High level, transistor T2 is in a non-conduction state, and the potential at node N1 is held by the gate capacitance of transistor T6.

When clock signal C1 varies to the Low level, capacitances exit between the gate and the drain and between the gate and the source of transistor T6, and therefore node N1 is lowered from a potential (VSS+Vt) to a voltage lower than the Low level by the bootstrap effect of these capacitances. Accordingly, a voltage larger than the threshold voltage is applied between the gate and source of transistor T6, transistor T6 maintains conduction, and the Low level of clock signal C1 is output as signal OUT1.

Successively, during period P3, when clock signal C3 varies to the Low level, transistor T4 is in a conduction state and the potential of node N2 varies from High level to a potential (VSS+Vt) that is higher than Low level added to threshold voltage Vt. Accordingly, transistors T1 and T5 are in a conduction state, node N1 and signal OUT1 vary to the High level. At this time, since the potential difference between the gate and source of transistor T6 is zero, transistor T6 is in a non-conduction state.

During period P3 and subsequent periods, since the Low level of clock signal C3 is input to transistor T4 at constant intervals, node N2 is kept at potential (VSS+Vt). Therefore, transistors T1 and T5 maintain conduction. This state is maintained until start pulse ST becomes the Low level.

As described above, the operation of shift register SR1 has been explained, and the same operation of periods P1 to P3 is executed in all shift registers, except that input signals vary in the other shift registers. With this operation, outputs from scanning circuit 1 sequentially become the Low level.

Output signals from shift register SRn are used in a liquid crystal panel on which scanning circuit 1 is mounted.

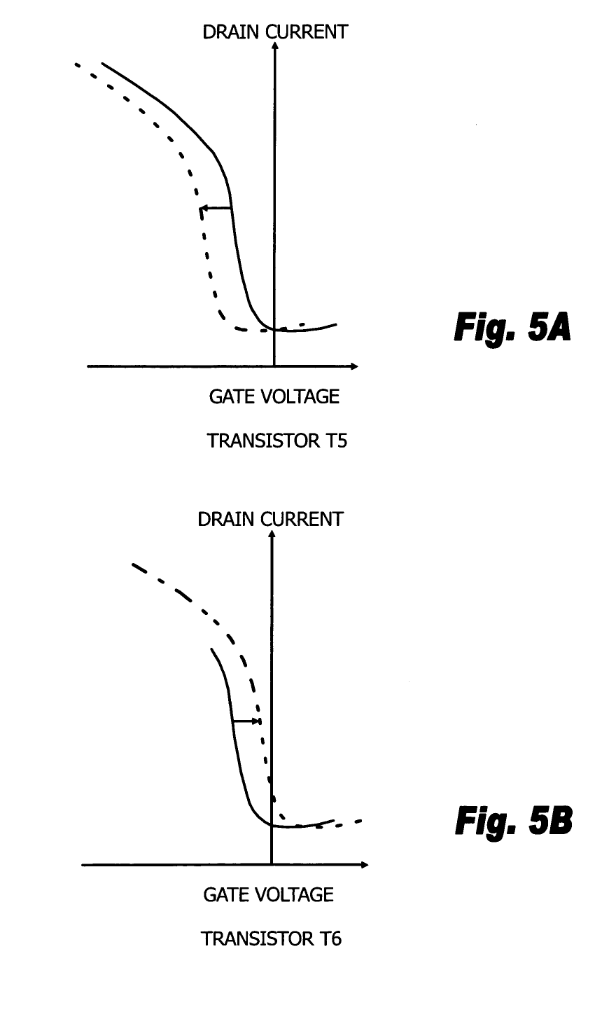

Now, when transistors T5 and T6 are operated for a long period, static characteristics vary in constant directions. FIGS. 5A and 5B show measurement results of static characteristics when an operation test is performed under a predetermined driving condition at temperature of 80° C. Incidentally, solid lines in FIGS. 5A and 5B indicate static characteristics prior to the operation test (0 hour) and dashed lines indicate static characteristics after 500 hours elapsed.

As shown in FIG. 5A, the static characteristic of transistor T5 varies in a negative direction, i.e., in a direction in which the absolute value of the threshold voltage increases after transistor T5 is operated for a long period. Also, as shown in FIG. 5B, the static characteristic of transistor T6 varies in a positive direction, i.e., in a direction in which the absolute value of the threshold voltage decreases after transistor T6 is operated for a long period.

Incidentally, the temperature environment (80° C.) of this operation test does not always coincide with the actual operation condition. Since this operation test is performed under the high-temperature environment, it also serves as an acceleration test that is used to evaluate reliability. Therefore, to measure changes of static characteristics after the operation test at temperature of 80° C. for 500 hours is an effective means for estimating the operating life of the semiconductor device.

In the first embodiment, the absolute value of the initial threshold of transistor T5 is smaller than the absolute value of the initial threshold of transistor T6. Also, in a plurality of transistors in which the thresholds that are required in the circuit design are equal, transistor T5 having the initial threshold at the lower limit within the acceptable range of the required threshold is arranged at a circuit position where the absolute value of the threshold voltage increases by operating, and transistor T6 having the initial threshold at the upper limit within the acceptable range of the required threshold is arranged at a circuit position where the absolute value of the threshold voltage decreases by operating. Incidentally, the required thresholds in circuit design of transistors T1 to T5 are equal.

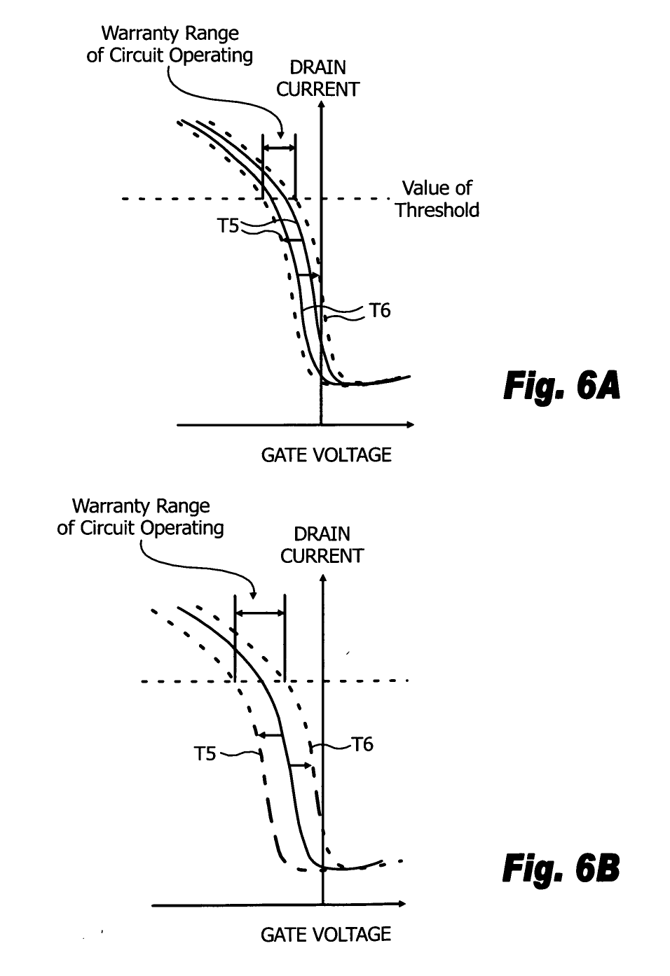

In the semiconductor device according to first embodiment, as shown in FIG. 6A, the static characteristics of transistors T5 and T6 vary in opposite directions as time passes. In other words, the static characteristic of transistor T5 varies in the negative direction (the direction in which the absolute value of the threshold voltage increases) and the static characteristic of transistor T6 varies in the positive direction (the direction in which the absolute value of the threshold voltage decreases). Therefore, since the thresholds of two transistors T5, T6 vary in directions to compensate for a difference of initial thresholds, the difference between the thresholds of two transistors T5, T6 does not increase beyond the warranty range. Accordingly, even if the scanning circuit is operated for a long period, the scanning circuit operates stably without malfunction.

On the other hand, in a general scanning circuit to which the present invention is not applied, the initial static chrematistics of transistors T5 and T6 are set as equally as possible. Therefore, when this scanning circuit is operated for a long period, as shown in FIG. 6B, the static characteristics of transistors T5 and T6 vary in mutually opposite directions, and are in the acceptable range of the required threshold, i.e., the warranty range of the circuit operation. As a result, the operation of the scanning circuit becomes unstable.

Next, the effects of the first embodiment are explained. The inventors tested and studied in order to solve the problem that the operation of the above-mentioned thin film transistor, especially, low-temperature polysilicon thin film transistors became unstable with the passage of time. Accordingly, the semiconductor circuit including a group of transistors that were evenly formed, was operated for a long period under a prescribed driving condition, and the inventors found that the respective transistors were different in degradation conditions and in variation directions of threshold voltages. Specifically, the inventors found that the absolute value of the threshold was large in one transistor and the absolute value of the threshold was small in another transistor.

This phenomenon indicates that, when a semiconductor device including a group of transistors that are manufactured to provide a constant characteristic is operated for a long period, threshold voltages of the plurality of transistors, which were initially equal, vary in directions apart from one another. Such a phenomenon presents no problem when the operating voltage is high and the acceptable range of the threshold voltage is wide. However, when the power supply voltage is reduced for high-speed operation and small deign, or when the power supply voltage is reduced in order to reduce power consumption, there is a major problem because the acceptable range of the operating voltage is narrow.

Therefore, the inventors completed the present invention to develop the technique for preventing malfunctions by setting the initial threshold voltage of each transistor in accordance with the variation direction of the threshold voltage that is expected for each transistor in a manner that variations in threshold voltages of respective transistors are not beyond a constant range.

For example, according to the first embodiment, the absolute value of the initial threshold of transistor T5 is set to be smaller than the absolute value of the initial threshold of transistor T6. With this arrangement, even if scanning circuit 1 is operated for a long period, the characteristics of two transistors vary in directions to compensate for the difference of initial thresholds, and therefore there is no case in which the difference of thresholds of two transistors exceeds the warranty range of the circuit operation. Accordingly, it is possible to obtain a semiconductor device that operates stably even if being operated for a long period.

The effects of the first embodiment are specially enhanced when the acceptable range of the operating voltage is narrow by reducing the power supply voltage of the semiconductor device for the purpose of providing higher speed, small design, or lower power consumption in the semiconductor device. According to the semiconductor device of the first embodiment, even if the acceptable range of the operating voltage is narrow, malfunctions caused by a change of threshold voltages of transistors can be reduced and shortening of the operating life of the semiconductor device can be prevented.

In the first embodiment, the example in which scanning circuit 1 includes P-channel transistors is mentioned, however, scanning circuit 1 may include N-channel transistors. Also, scanning circuit 1 in the liquid crystal display panel is taken as an example of the semiconductor device, however, the present invention is not limited to this and may be applied to any semiconductor device.

Incidentally, it can be determined whether the absolute value of a threshold of a transistor that is arranged at any position in a circuit increases or decreases after operating the circuit for a long period, for example, by developing a prototype of a circuit to be designed and measuring thresholds of the transistor before and after an acceleration test.

### Second Embodiment

Next, the second embodiment of the present invention is explained.

As shown in FIG. 7, in the semiconductor device according to the second embodiment, channel region 6 and gate electrode 9 in transistor T6 are longer than those of transistor T5. For example, assume that lengths of channel region 6 and gate electrode 9 in transistor T6 are 3 μm and lengths of channel region 6 and gate electrode 9 in transistor T5 are 1 μm. Assume that doping concentrations of channel regions 6 in transistors T5 and T6 are equal. With this arrangement, the absolute value of the initial threshold of transistor T6 is set to the upper limit within the acceptable range of the required threshold, and the absolute value of the initial threshold of transistor T5 is set to the lower limit within the acceptable range of the required threshold. Therefore, also, in the semiconductor device according to the second embodiment, the absolute value of the initial threshold of transistor T6 is larger than the absolute value of the initial threshold of transistor T5.

The second embodiment is similar to the first embodiment in the construction, operation, and effects, except for the above-mentioned.

In the semiconductor device according to the second embodiment, the initial threshold voltage of each transistor is set in accordance with the variation direction of the threshold voltage, that is required for each transistor, in a manner that variations in threshold voltages of respective transistors are not beyond a prescribed range, thereby malfunctions caused by a change of threshold voltages of transistors can be reduced and shortening of the operating life of the semiconductor device can be prevented, similarly to the first embodiment.

### Third Embodiment

Next, a semiconductor device according to the third embodiment of the present invention is explained.

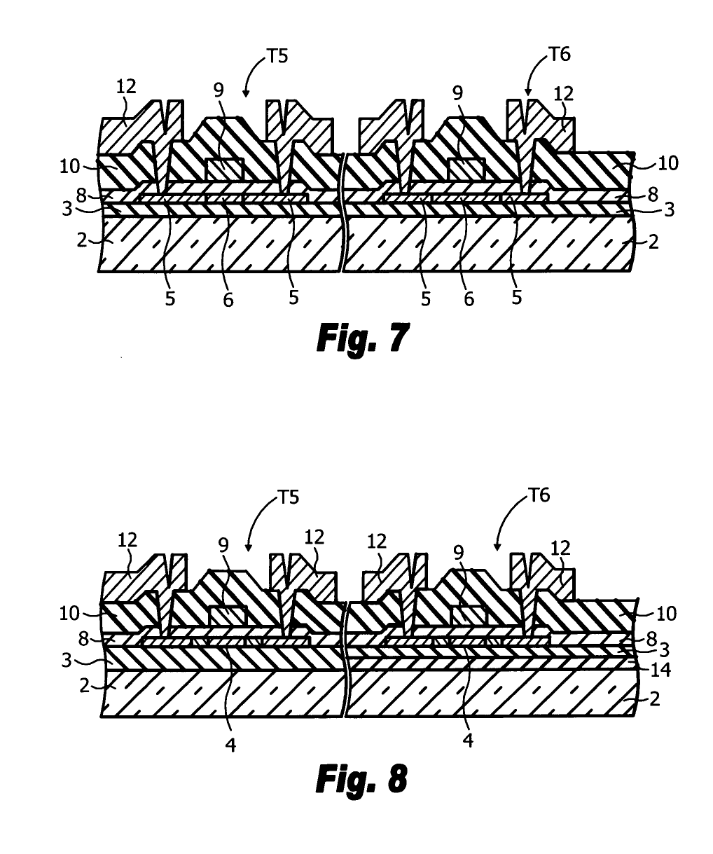

As shown in FIG. 8, the semiconductor device according to the third embodiment is provided with silicon nitride film 14 between transistor T6 and glass substrate 2. Silicon nitride film 14 is arranged between silicon oxide film 3 and glass substrate 2 only in the region where transistor T6 is formed.

Also, according to the third embodiment, crystal grains in polycrystalline silicon film 4 of transistor T6 are formed smaller than those in polycrystalline silicon film 4 of transistor T5. With this arrangement, the absolute value of the initial threshold of transistor T6 is set to the upper limit within the acceptable range of the required threshold, and the absolute value of the initial threshold of transistor T5 is set to the lower limit within the acceptable range of the required threshold. Therefore, also, in the semiconductor device according to the third embodiment, the absolute value of the initial threshold of transistor T6 is larger than the absolute value of the initial threshold of transistor T5.

The third embodiment is similar to the first embodiment in the construction, operation, and effects, except for the above-mentioned.

In the semiconductor device according to the third embodiment, the initial threshold voltage of each transistor is set in accordance with the variation direction of the threshold voltage, which is required for each transistor, in a manner that variations in threshold voltages of respective transistors are not beyond a prescribed range, thereby malfunctions caused by a change of threshold voltages of transistors can be reduced and shortening of the operating life of the semiconductor device can be prevented, similarly to the first embodiment.

### Fourth Embodiment

Next, the fourth embodiment of the present invention is explained.

A semiconductor device according to the fourth embodiment is an example in which a scanning circuit is made up of a CMOS circuit.

As shown in FIG. 9, in the semiconductor device according to the fourth embodiment, in order to form the CMOS circuit, P-channel transistor 16 and N-channel transistor 17 are formed on glass substrate 2.

In the semiconductor device according to the fourth embodiment, initial threshold voltages are set to different values in accordance with the variation direction of the time-varying threshold voltage in each transistor, between P-channel transistor 16 and N-channel transistor 17, which are paired to form the CMOS circuit or between similar conductive transistors.

The fourth embodiment is similar to the first embodiment in the construction, operation, and effects, except for the above-mentioned.

In the semiconductor device according to the fourth embodiment, the initial threshold voltage of each transistor is set in accordance with the variation direction of threshold voltage, which is required for each transistor, in a manner that variations in threshold voltages of respective transistors are not beyond a prescribed range, thereby malfunctions caused by a change of threshold voltages of transistors can be reduced and shortening of the operating life of the semiconductor device can be prevented, similarly to the first embodiment.

### Fifth Embodiment

Next, a semiconductor device according to the fifth embodiment of the present invention is explained.

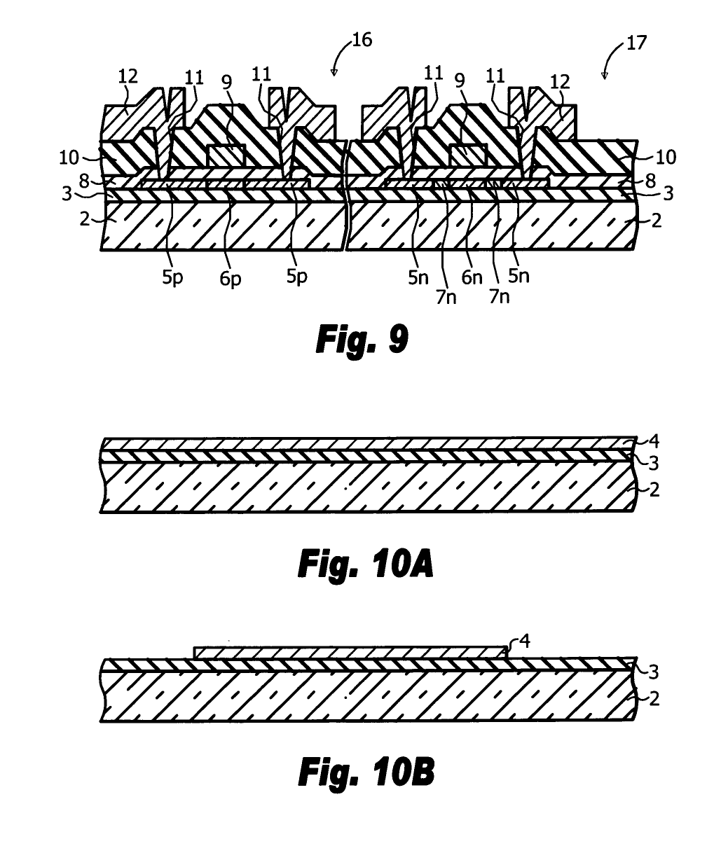

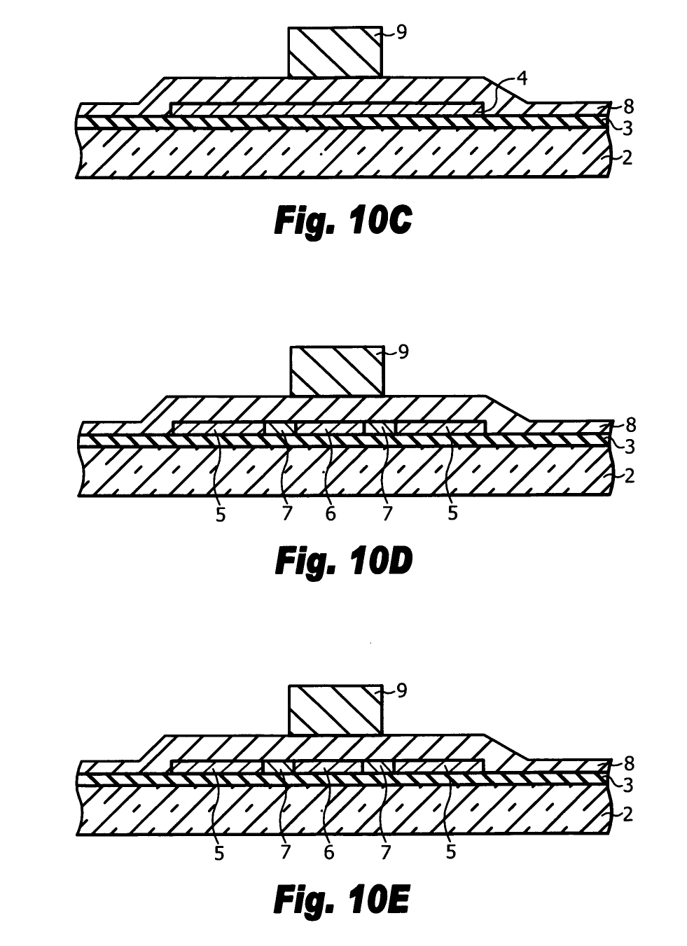

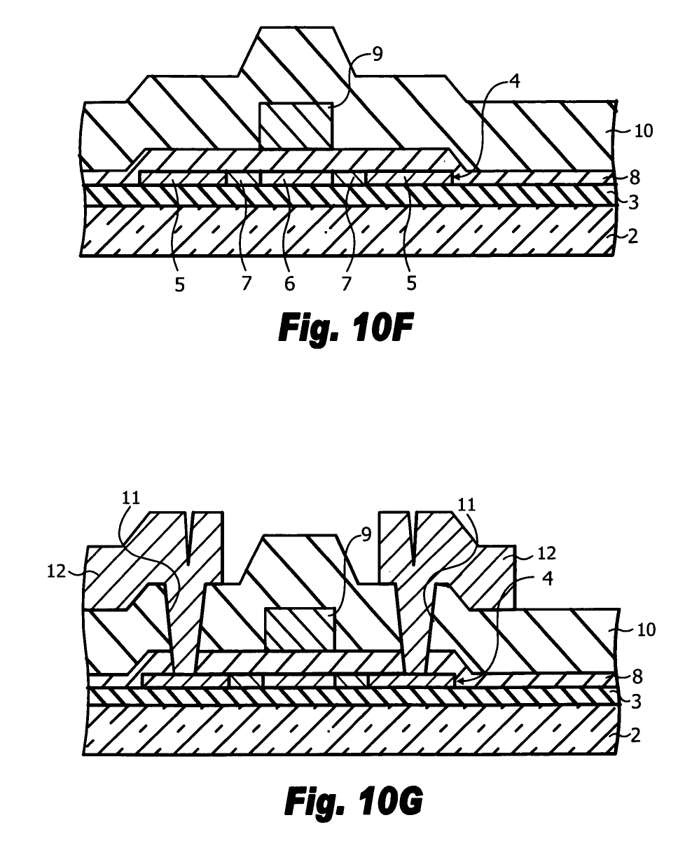

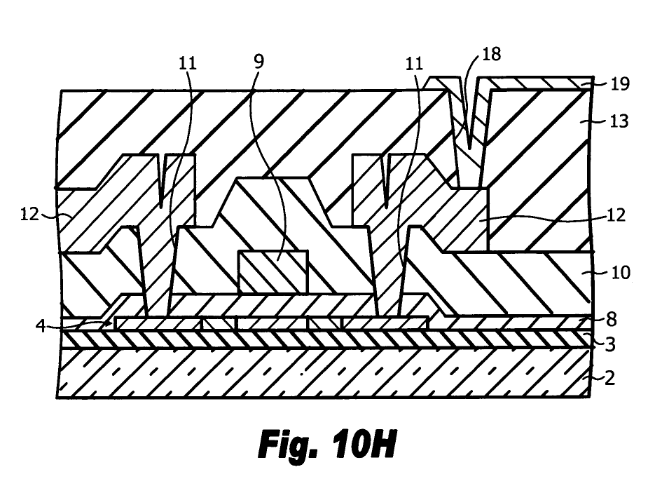

In the fifth embodiment, explanations are given of a method of manufacturing the semiconductor device described in the first embodiment. As shown in FIG. 10A, first, silicon oxide film 3 that will become a substrate protection film is formed on glass substrate 2, and an amorphous silicon film is formed on silicon oxide film 3.

Successively, in order to set the threshold of a transistor to a desirable value, impurity ions to be doped are implanted into a portion that will become a channel region of the transistor on the amorphous silicon film by using an ion implanter. At this time, conventionally, each channel area of transistors T1 to T6 (see FIG. 2) is doped with an equal concentration.

On the other hand, according to the fifth embodiment, in order to set the threshold voltage of transistor T5 and the threshold voltage of transistor T6 to different values, impurity ions to be doped are implanted into the channel region of transistor T5 and the channel region of transistor T6 with different concentrations. For example, when the absolute value of the threshold voltage of transistor T6 is set higher than the absolute value of the threshold voltage of transistor T5 by 1.5V, a phosphorus of 1×10¹² cm⁻² dose is implanted into the channel region of transistor T5 and a phosphorus of 3×10¹² cm⁻² dose is implanted into the channel region of transistor T6.

Since the amount of ions for implantation that are to be doped is closely related to a laser crystallization process and a plasma hydrogenating process (described later), which are a following processes, the amount of ions for implantation is determined with consideration for these process.

After implanting ions to be doped, the laser light is irradiated to the amorphous silicon film to crystallize the amorphous silicon film. With this operation, polycrystalline silicon film 4 is formed.

Next, as shown in FIG. 10B, polycrystalline silicon film 4 is patterned in an island shape by a known photolithography method and dry-etching method. After that, a washing process is performed, as appropriate.

Then, as shown in FIG. 10C, gate insulating film 8 is formed on silicon oxide film 3 so as to cover polycrystalline silicon film 4. Further, a conductive film is formed on gate insulating film 8 and the conductive film is patterned in a desirable shape to form gate electrode 9. Gate electrode 9 is formed on the channel region of the transistor, i.e., a portion directly above polycrystalline silicon film 4.

Then, as shown in FIG. 10D, regions to be a source and a drain of polycrystalline silicon film 4 are exposed, a resist (not shown) is formed to cover the remaining regions by using a photolithography technique, and boron is implanted by using the resist as a mask. At this time, the concentration of boron implanted is higher than the concentration of boron to be implanted to form an LDD region, which will be described later.

This implantation process is performed, for example, by an ion implanter in which boron ions are mass-separated or by an ion doping apparatus for accelerating and implanting ions without mass separation. With this operation, source/drain region 5 is formed.

Then, as shown in FIG. 10E, the resist is peeled, and boron is implanted to form the LDD region by using gate electrode 9 as a mask. In this case, since it is necessary to control the concentration of boron so that it is lower than that in the process of forming source/drain region 5, the ion implantation method may be preferably used rather than the ion doping method.

With this operation, LDD region 7 can be formed to be self-aligning. At this time, a portion between LDD regions 7 in polycrystalline silicon film 4 becomes channel region 6. After that, the activation process for impurities is performed.

Additionally, since the boron implantation process for forming LDD region 7 is applied to the whole substrate, the concentration of boron to be implanted into LDD region 7 is equal in each transistor. Therefore, differences are generated in the resistance values of LDD region 7 in each transistor, caused by the difference in the concentration of phosphorus that is implanted into the channel region in the step shown in FIG. 10A. Specifically, since the concentration of phosphorus implanted into the channel region of transistor T6 is higher than the concentration of phosphorus implanted into the channel region of transistor T5 and the amount of N-type impurities (phosphorus) combined with P-type impurities (boron) is large, the resistance value of LDD region 7 becomes higher.

To eliminate differences in the resistance values of LDD regions 7 in transistors, phosphorus may be selectively implanted into only the channel region or the concentration of boron may be changed to meet the difference in the concentration of phosphorus in the boron implantation step for forming LDD region 7 shown in FIG. 10E.

Then, as shown in FIG. 10F, interlayer insulating film 10 is formed on gate insulating film 8 so as to cover gate electrode 9. Successively, the plasma hydrogenating process is performed to terminate the remaining dangling bonds of silicon in polycrystalline silicon film 4 by hydrogen in order that the remaining dangling bonds are inactive.

Next, as shown in FIG. 10G, contact hole 11 is formed in interlayer insulating film 10 above source/drain region 5 of the transistor. Then, a conductive layer that is connected to source/drain region 5 through contact hole 11 is formed on interlayer insulating film 10, and the conductive layer is patterned to form wire 12. With these operations, transistors T1 to T6 are connected in accordance with the circuit shown in FIGS. 1 and 2. Therefore, scanning circuit 1 shown in FIGS. 1 and 3 is completed.

Additionally, various circuits are formed on the TFT substrate of the liquid crystal display panel in addition to scanning circuit 1. For example, transistors for driving pixels are arranged in the display region of the TFT substrate so as to correspond to a plurality of pixels.

When the transistors for driving pixels are formed, after the steps shown in FIGS. 10A to 10G, as shown in FIG. 10H, planarization film 13 that also serves as a protection film is formed on interlayer insulating film 10 so as to cover wire 12, and contact hole 18 is formed in planarization film 13. Contact hole 18 is formed so as to reach wire 12 connected to the source or the drain, from among wires 12 connected to source/drain region 5 of each transistor.

Successively, transparent electrode 19 that connects to wire 12 through contact hole 18 is formed on planarization film 13. With this arrangement, a TFT substrate is completed.

Finally, the TFT substrate and a well known opposite substrate are joined in parallel through a seal material to provide a space, and liquid crystal is sealed between the TFT substrate and the opposite substrate to form a liquid crystal layer. With this arrangement, the liquid crystal display panel is completed.

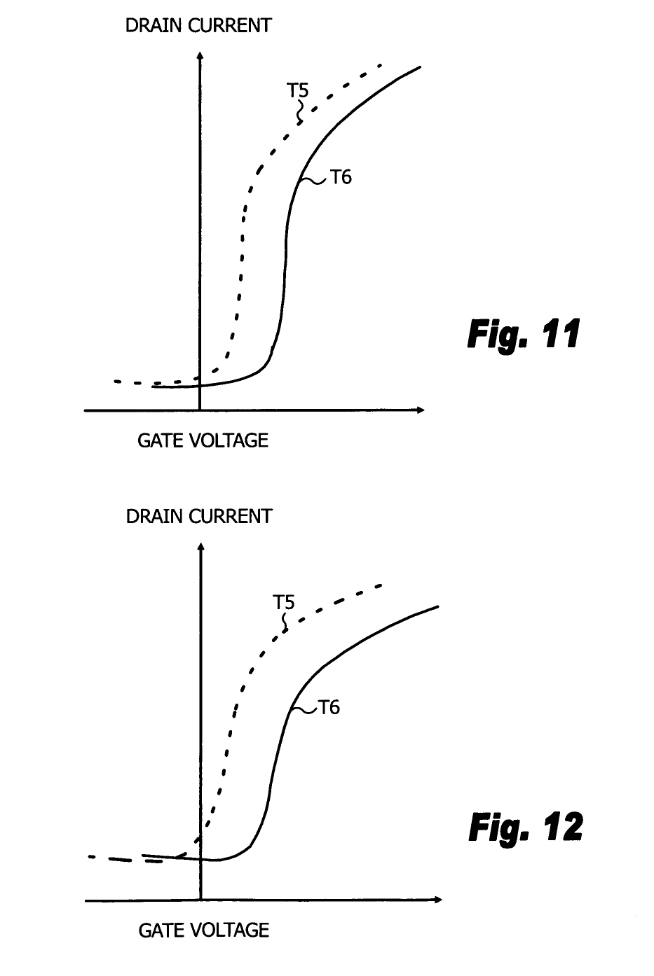

In the method of manufacturing the semiconductor device according to the fifth embodiment, in the step shown in FIG. 10A, the amounts of phosphorus to be implanted into the formation regions of the channel regions for transistors T5 and T6 are set differently, thereby setting the doping concentrations of the channel regions for transistors T5 and T6 to different values. With this arrangement, as shown in FIG. 11, the absolute value of the threshold voltage of transistor T5 can be set smaller then the absolute value of the threshold voltage of transistor T6 by approximately 1.5V. Incidentally, the polarity of the longitudinal axis in FIG. 11 and FIGS. 12 and 13, which will be described later, is opposite to that in FIGS. 5A, 5B, 6A, and 6B.

The fifth embodiment describes the example in which the threshold voltages of P-channel transistors in the scanning circuit are set to different values, however, when the scanning circuit includes N-channel transistors, the same effect can be also obtained, by selecting the kinds and concentrations of impurities to be implanted into channel regions, as appropriate.

### Sixth Embodiment

Next, a semiconductor device according to the sixth embodiment of the present invention is explained.

In the sixth embodiment, explanations are given of a method of manufacturing the semiconductor device described in the second embodiment.

Incidentally, the method of manufacturing the semiconductor device described in the sixth embodiment is similar to the method of manufacturing the semiconductor device described in the fifth embodiment. Therefore, the method of manufacturing the semiconductor device according to the sixth embodiment is explained below, with reference to FIGS. 10A to 10H, similarly to the fifth embodiment.

In the sixth embodiment, as shown in FIG. 10A, first, silicon oxide film 3 which is to act as a substrate protection film is formed on glass substrate 2, and an amorphous silicon film is formed on silicon oxide film 3.

Successively, in order to set the threshold of a transistor to a desirable value, impurity ions to be doped are implanted into a portion which will become a channel region of the transistor on the amorphous silicon film by using an ion implanter. At this time, in the fifth embodiment, impurity ions to be doped are implanted into the channel region of transistors T5 and the channel region of transistors T6 in different concentrations. In the sixth embodiment, impurity ions to be doped are implanted into the channel region of each transistor with an equal concentration, similarly to the conventional semiconductor device.

After implanting ions to be doped, laser light is irradiated to the amorphous silicon film to crystallize it. With this operation, polycrystalline silicon film 4 is formed.

Next, as shown in FIG. 10B, polycrystalline silicon film 4 is patterned in an island shape by a known photolithography process and dry-etching process. After that, a washing process is performed, as appropriate.

Then, as shown in FIG. 10C, gate insulating film 8, for example, 50 nm in thickness, is formed on silicon oxide film 3 so as to cover polycrystalline silicon film 4. Further, a conductive film is formed on gate insulating film 8 and the conductive film is patterned to form gate electrode 9. At this time, in the fifth embodiment, the length of gate electrode 9 of each transistor is made equal, however, in the sixth embodiment, as shown in FIG. 7, gate electrode 9 of transistor T6 is formed to be longer than gate electrode 9 of transistor T5. For example, the length of gate electrode 9 of transistor T6 is 3 μm and the length of gate electrode 9 of transistor T5 is 1 μm.

Successively, boron is implanted into polycrystalline silicon film 4 by using gate electrode 9 as a mask to form source/drain region 5 to be self-aligning. At this time, the region between source/drain regions 5 in polycrystalline silicon film 4 is channel region 6.

In the method of manufacturing the semiconductor device according to the sixth embodiment, since the lengths of gate electrodes 9 of transistors T5 and T6 are different, the lengths of channel regions 6 that are formed by using gate electrodes 9 as the mask are also different. Specifically, the length of channel region 6 in transistor T6 is 3 μm and the length of channel region 6 in transistor T5 is 1 μm.

The following steps are similar to those of the fifth embodiment. With this arrangement, the semiconductor device shown in FIG. 7 is completed.

According to the sixth embodiment, since the channel regions of transistors T5 and T6 are different in length, as shown in FIG. 12, the absolute value of the threshold voltage of transistor T5 can be made smaller than the absolute value of the threshold voltage of transistor T6, for example, by 1.0V.

In the method of manufacturing the semiconductor device according to the sixth embodiment, it is unnecessary to perform the step of implanting ions to be doped twice to vary the doping concentration of the channel region of each transistor, as in the fifth embodiment. Therefore, the threshold voltage of each transistor can be set to different values without increasing the number of steps.

Incidentally, the length of channel region 6 of the transistors can be set to different values, by optimally designing the exposure mask used in the step of patterning the gate electrode. Specifically, aperture lengths for gate electrodes arranged in the exposure mask may be set to different values in accordance with transistors.

### Seventh Embodiment

Next, a semiconductor device according to the seventh embodiment of the present invention is explained.

In the seventh embodiment, explanations are given of a method of manufacturing the semiconductor device described in the third embodiment.

In the seventh embodiment, as shown in FIG. 8, silicon nitride film 14 that is 100 nm in thickness is formed in the region where transistor T6 is formed on glass substrate 2.

Successively, silicon oxide film 3 is formed on glass substrate 2 so as to cover silicon nitride film 14, and then an amorphous silicon film is formed.

Then, impurity ions to be doped are implanted into a portion which will become a channel region of each transistor, with an equal concentration, similarly to the sixth embodiment. After that, laser light is irradiated to the amorphous silicon film to crystallize the amorphous silicon film. With this operation, polycrystalline silicon film 4 is formed. The following steps are similar to those of the fifth embodiment. With this arrangement, the semiconductor device shown in FIG. 8 is completed.

According to the seventh embodiment, in the formation region of transistor T6, silicon nitride film 14 is formed between glass substrate 2 and silicon oxide film 3. With this arrangement, the structure of the substrate protection film in a region directly below transistor T6 is different from that of the region directly below transistor T5. In other words, silicon oxide film 3 made of a single layer is arranged in the region directly below transistor T6 as the substrate protection film while a two-layer film including silicon nitride film 14 and silicon oxide film 3 is arranged in the region directly below transistor T5 as the substrate protection film. Since the thermal conductivity of the silicon nitride film is higher than that of the silicon oxide film, cooling is promoted when laser light is irradiated to the amorphous silicon film to be crystallized. Therefore, crystal gains in polycrystalline silicon film 4 of transistor T6 are smaller than those in polycrystalline silicon film 4 of transistor T5.

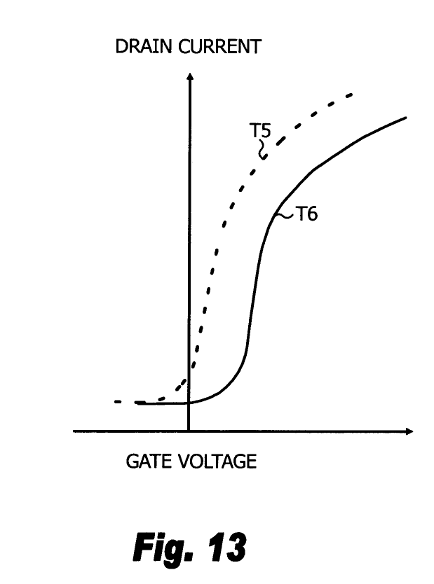

As a result, as shown in FIG. 13, the absolute value of the threshold of transistor T6 can be made larger than the absolute value of the threshold of transistor T5 by approximately 0.5V.

As described above, in the seventh embodiment, the substrate protection films of transistors are made different to vary the crystallization behavior in the amorphous silicon film. Incidentally, the crystallization behavior in the amorphous silicon film may be varied by selectively controlling the laser irradiation strength.

### Eighth Embodiment

Next, a semiconductor device according to the eighth embodiment of the present invention is explained.

In the eighth embodiment, explanations are given of a method of manufacturing the semiconductor device described in the fourth embodiment.

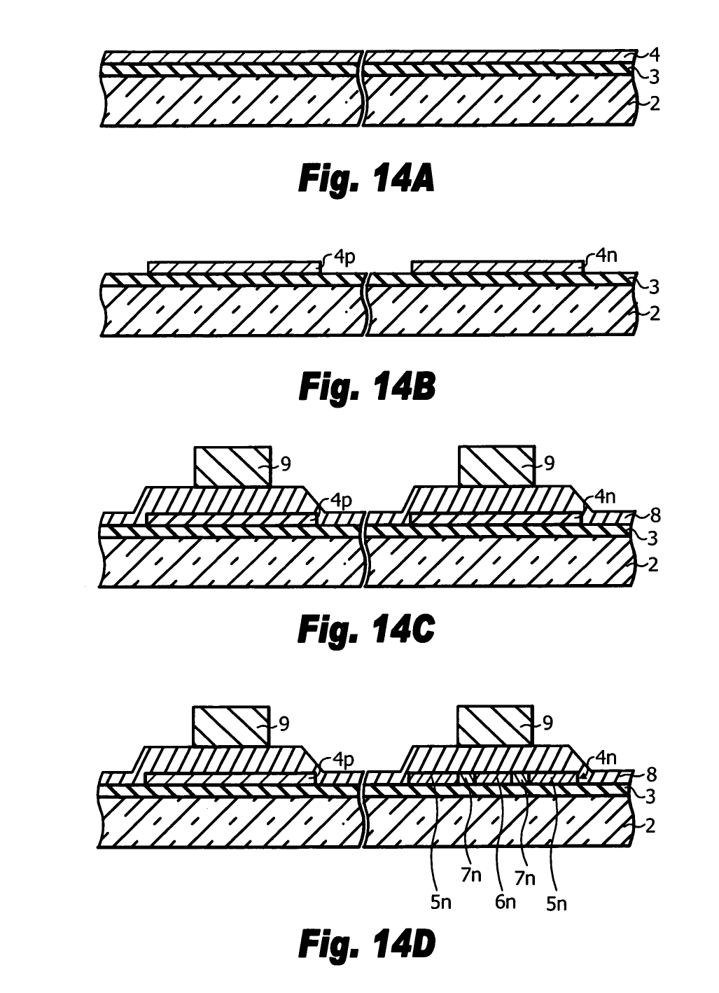

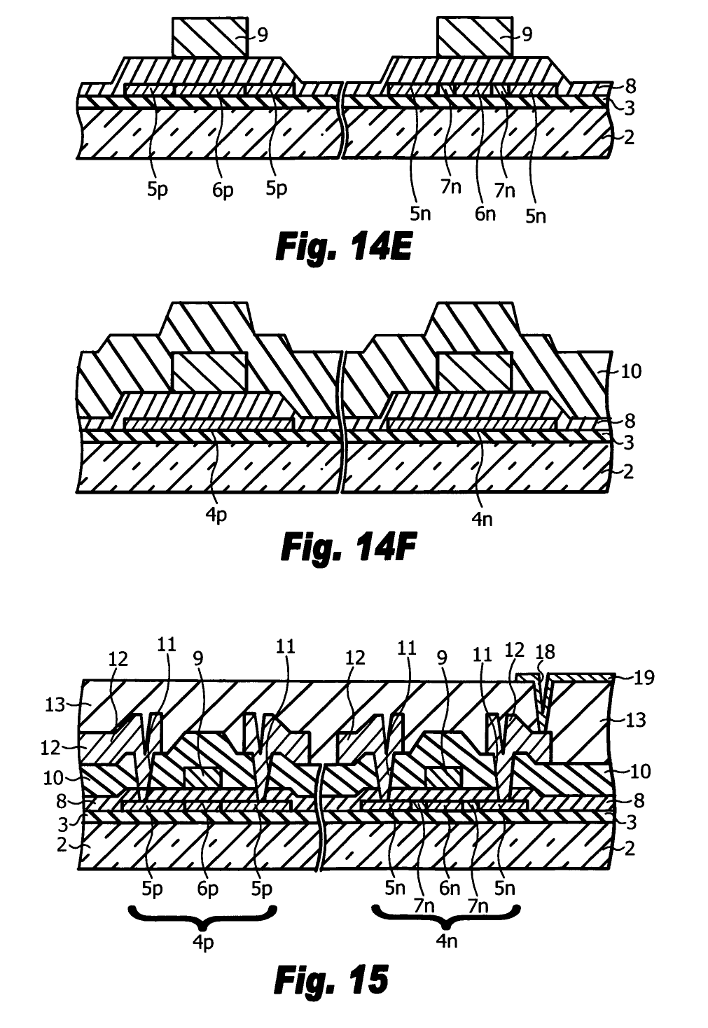

As shown in FIG. 14A, first, silicon oxide film 3 which will act as a substrate protection film is formed on glass substrate 2, and an amorphous silicon film is formed on silicon oxide film 3.

Successively, in order to set the threshold of a transistor to a desirable value, impurity ions to be doped are implanted into a region which will become a channel region of the transistor on the amorphous silicon film.

For example, boron having a 5×10¹² cm⁻² dose is implanted into a region where a N-channel transistor is formed, and phosphorus having a 3×10¹² cm⁻² dose is implanted into a region where a P-channel transistor is formed. The kinds and amounts of impurities may be adjusted to meet a design value, as appropriate.

Incidentally, in order to shorten steps, for example, after phosphorus is implanted into the whole surface, another dope ion may be implanted, as a counter, into only the region where N-channel transistor is formed. As a method of implanting impurities, an ion implantation method and an ion doping method are mentioned. Also, when phosphorus is implanted into the whole surface, as described above, impurity elements may be implanted in vapor while the amorphous silicon film is formed. After implanting impurities, laser light is irradiated to the amorphous silicon film to crystallize the amorphous silicon film. With this arrangement, polycrystalline silicon film 4 is formed.

Next, as shown in FIG. 14B, polycrystalline silicon film 4 is patterned in an island shape by a known photolithography method and dry-etching method. At this time, the portion where boron is implanted in polycrystalline silicon film 4 becomes polycrystalline silicon film 4n and the active layer of the N-channel transistor. On the other hand, the portion where phosphorus is implanted in polycrystalline silicon film 4 becomes polycrystalline silicon film 4p and the active layer of the P-channel transistor. After that, a washing process is performed, as appropriate.

Then, as shown in FIG. 14C, gate insulating film 8 is formed on silicon oxide film 3 so as to cover polycrystalline silicon films 4n, 4p. Further, a conductive film is formed on gate insulating film 8 and the conductive film is patterned in a desirable shape to form gate electrode 9. Gate electrode 9 is formed on the channel region of the transistor, i.e., a portion directly above polycrystalline silicon film 4.

Then, as shown in FIG. 14D, regions that are to be a source and a drain of polycrystalline silicon film 4n are exposed, a resist (not shown) is formed to cover the remaining regions by using the photolithography technique, and phosphorus is implanted using the resist as a mask, for example, at a dose of 1×10¹⁵ cm⁻². With this arrangement, source/drain region 5n of the N-channel transistor is formed. After that, the resist is peeled, and phosphorus is implanted using gate electrode 9 as a mask, for example, at a dose of 1×10¹³ cm⁻² to form LDD region 7n. A portion between LDD regions 7n in polycrystalline silicon film 4n is channel region 6n.

Then, as shown in FIG. 14E, boron is implanted into polycrystalline silicon film 4p by using gate electrode 9 as a mask, for example, at a dose of 2×10¹⁵ cm⁻². With this operation, source/drain region 5p of the P-channel transistor is formed in polycrystalline silicon film 4p. At this time, a portion between source/drain regions 5p in polycrystalline silicon film 4p is channel region 6p.

As described above, according to the eighth embodiment, N-channel transistor 17 is formed to a LDD type and P-channel transistor 16 is formed to a self-aligning type. Here, impurity ions to be doped may be implanted by an iron implantation apparatus where mass separation is performed or by an ion doping apparatus for accelerating and implanting ions without mass separation. Incidentally, when an LDD region is formed, it is necessary to control the implantation amount with a concentration lower than that of the source/drain region, and thus the ion implantation method may be preferably used rather than the ion doping method.

Then, as shown in FIG. 14F, interlayer insulating film 10 is formed on gate insulating film 8 so as to cover gate electrode 9. Then, it is held, for example, at a temperature of 450° C. for one hour to activate impurities. Successively, the plasma hydrogenating process is performed to inactivate remaining silicon dangling bonds in polycrystalline silicon film 4.

Finally, as shown in FIG. 9, contact hole 11 that reaches the source/drain region is formed in interlayer insulating film 10. Then, a conductive layer is formed in interlayer insulating film 10 and in inside contact hole 11, and the conductive layer is patterned to form wire 12. With these operations, a CMOS circuit is formed.

Further, when a transistor for a pixel circuit is formed, as shown in FIG. 15, planarization film 13 is formed on interlayer insulating film 10 so as to cover wire 12, and contact hole 18 is formed so as to pass through planarization film 13. Then, transparent electrode 19 that connects to wire 12 through contact hole 18 is formed on planarization film 13.

In the eighth embodiment, initial threshold voltages are set to different values in accordance with the variation direction of the time-varying threshold voltage in each transistor, between the P-channel transistor and N-channel transistor 17, which are paired to form the CMOS circuit or between similar conductive transistors.

As ways of setting threshold voltage to different values, there is a method in which the amounts of impurities to be implanted into the channel regions at the step shown in FIG. 14A are made different, similarly to the fifth embodiment, a method in which the lengths of channel regions are made different by setting the gate electrodes to different lengths at the step shown in FIG. 14C, similarly to the sixth embodiment, and a method in which the silicon nitride film is arranged between glass substrate 2 and silicon oxide film 3 at the step shown in FIG. 14A, similarly to the seventh embodiment. One of these methods may be used or two or more methods may be combined. The other manufacturing method is similar to the fifth embodiment.

### Ninth Embodiment

Next, a semiconductor device according to the ninth embodiment of the present invention is explained.

The ninth embodiment is an example in which the present invention is applied to a liquid crystal display panel.

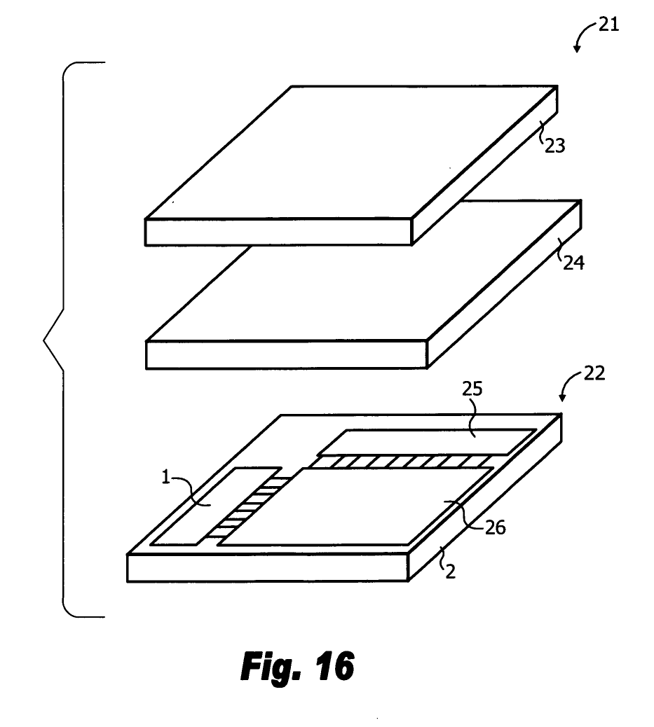

As shown in FIG. 16, liquid crystal display panel 21 according to the ninth embodiment is provided with TFT substrate 22 and opposite substrate 23, which are arranged in parallel to provide a mutual space. Liquid crystal layer 24 is arranged between TFT substrate 22 and opposite substrate 23.

TFT substrate 22 is provided with glass substrate 2. Scanning circuit 1, described in the first to fourth embodiments, data circuit 25, and pixel circuit 26 are formed on the surface of glass substrate 2, which is arranged at the opposite side of opposite substrate 23. Incidentally, data circuit 25 and pixel circuit 26 are manufactured by the same steps as scanning circuit 1.

In the ninth embodiment, since the scanning circuit described in the first to fourth embodiments is arranged on glass substrate 2, there are little variations in the threshold voltage of each transistor after a long period of operation, and it operates stably. Therefore, liquid crystal display panel 21 with a long operating life can be obtained.

### Tenth Embodiment

Next, a semiconductor device according to the tenth embodiment of the present invention is explained.

The tenth embodiment is an example in which the present invention is applied to an electronic device (a liquid crystal display panel in a mobile telephone).

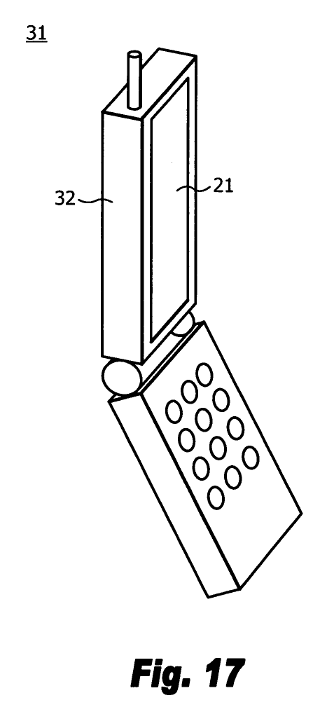

As shown in FIG. 17, mobile telephone 31 is provided with housing 32, which is a main body, and a display portion arranged inside housing 32. Liquid crystal display panel 21 described in the ninth embodiment is used as the display portion.

According to the tenth embodiment, even if mobile telephone 31 is operated for a long period, there is no case in which liquid crystal display panel 21 operates unstably. Incidentally, mobile telephones are often used in hostile operating environments, like the outdoors, as compared with usual electronic devices. Therefore, thresholds of transistor can be set for each product in accordance with the operating environment thereof, regarding mobile telephones that are used in extreme cold environments or mobile telephones that are used in warm environments.

Additionally, in the tenth embodiment, a mobile telephone is described as the example of electronic devices, however, the present invention is not limited to the mobile telephone and may be applied to electronic devices, such as a PDA (Personal Digital Assistance), a personal computer, and a digital video camera.

While preferred embodiments of the present invention have been described using specific terms, such description is for illustrative purposes only, and it is to be understood that changes and variations may be made without departing from the spirit or scope of the following claims.

What is claimed is:

1. A semiconductor device including a plurality of transistors in which the thresholds that are required in the circuit design are equal, wherein:
a transistor having an initial threshold at a lower limit within an acceptable range of said required threshold is arranged at a circuit position where an absolute value of a threshold voltage increases by operating, and
a transistor having an initial threshold at an upper limit within an acceptable range of said required threshold is arranged at a circuit position where an absolute value of a threshold voltage decreases by operating.

2. The semiconductor device according to claim 1, wherein said transistor is a P-channel transistor, wherein said circuit position where the absolute value of the threshold voltage increases by operating is high potential side of a power supply voltage, and wherein said circuit position where the absolute value of the threshold voltage decreases by operating is low potential side of a power supply voltage.

3. The semiconductor device according to claim 1, wherein a doping concentration of a channel region in said transistor having the initial threshold at the lower limit within the acceptable range is different from a doping concentration of a channel region in said transistor having the initial threshold at the upper limit within the acceptable range.

4. The semiconductor device according to claim 1, wherein a length of a channel region in said transistor having the initial threshold at a lower limit within an acceptable range is shorter than a length of a channel region of said transistor having an initial threshold at an upper limit within an acceptable range.

5. The semiconductor device according to claim 1, further comprising a film that is arranged between said substrate and said transistor having the initial threshold at the lower limit within the acceptable range or said transistor having the initial threshold at the upper limit within the acceptable range, said film is made of a material which is different from said substrate in conductivity.

6. The semiconductor device according to claim 1, wherein said transistor is a thin film transistor formed on an insulating substrate.

7. A liquid crystal display panel comprising:
a first substrate in which the semiconductor device according to claim 1 is formed on a base;
a second substrate arranged in parallel with said first substrate to provide a space; and
a liquid crystal layer arranged between said first substrate and said second substrate.

8. An electronic device having the liquid crystal display panel according to claim 7.

9. An electronic device having the semiconductor device according to claim 1.

10. A method of manufacturing a semiconductor device including a plurality of transistors in which the thresholds that are required in the circuit design are equal, wherein, a transistor having an initial threshold at a lower limit within an acceptable range of said required threshold is arranged at a circuit position where an absolute value of a threshold voltage increases by operating, and a transistor having an initial threshold at an upper limit within an acceptable range of said required threshold is arranged at a circuit position where an absolute value of a threshold voltage decreases by operating.

11. The method of manufacturing the semiconductor device according to claim 10, wherein said transistor is a P-channel transistor, wherein said circuit position where the absolute value of the threshold voltage increases by operating is high potential side of a power supply voltage, and wherein said circuit position where the absolute value of the threshold voltage decreases by operating is low potential side of a power supply voltage.

12. The method of manufacturing the semiconductor device according to claim 10, wherein said step of forming transistors comprises the steps of:
forming a semiconductor film on a substrate;
patterning said semiconductor film to form an active layer of said transistors;
forming a gate insulating film of said transistors on said active layer;
forming gate electrodes of said transistors on said gate insulating film; and
implanting impurities into said active layer to form source/drain regions of said transistors:
wherein, in the step of forming said semiconductor film, the doping concentration of channel region in said transistor having the initial threshold at the lower limit within the acceptable range is different from a doping concentration of a channel region in said transistor having the initial threshold at the upper limit within the acceptable range.

13. The method of manufacturing the semiconductor device according to claim 10, wherein said step of forming transistors comprises the steps of:
forming a semiconductor film on a substrate;
patterning said semiconductor film to form an active layer of said transistors;
forming a gate insulating film of said transistors on said active layer;
forming a gate electrode of said transistors on said gate insulating film;
and
implanting impurities into said active layer to form source/drain regions of said transistors:
wherein, in the step of forming said source/drain regions, a length of a channel region in said transistor having the initial threshold at the lower limit within the acceptable range is shorter than a length of a channel region in said transistor having the initial threshold at the upper limit within the acceptable range.

14. The method of manufacturing the semiconductor device according to claim 10, wherein said step of forming transistors comprises the steps of:
forming a film on a substrate on which said transistor having the initial threshold at the lower limit within the acceptable range or said transistor having the initial threshold at the upper limit within the acceptable range is formed, said film is made of a material which is different from said substrate in conductivity;
forming an amorphous semiconductor film on said substrate;
crystallizing said amorphous semiconductor film to form a semiconductor film;
patterning said semiconductor film to form an active layer of said transistors;
forming a gate insulating film of said transistors on said active layer;
forming gate electrodes of said transistors on said gate insulating film; and
implanting impurities into said active layer to form source/drain regions of said transistors.
